(19) United States
(12) Patent Application Publication
(10) Pub. No.: US 2010/0058985 A1
(43) Pub. Date: Mar. 11, 2010

(54) Photoresist supply apparatus and photoresist supply method

(75) Inventors: Dong Ho Kim, Cheonan-si (KR); Soo Min Hwang, Hwaseong-si (KR)

Correspondence Address: HARNESS, DICKEY & PIERCE, P.L.C., P.O. BOX 8910, RESTON, VA, 20195, US

(73) Assignee: SEMES CO. LTD.

(21) Appl. No.: 12/585,230

(22) Filed: Sep. 9, 2009

(30) Foreign Application Priority Data
Sep. 10, 2008 (KR) 10-2008-0089155

(51) Int. Cl. C23C 16/00

(52) U.S. Cl. 118/720

(57) ABSTRACT

Provided is a photoresist supply apparatus. The photoresist supply apparatus includes a discharge nozzle, a metering pump, a trap tank, a bottle, and a first drain line. The discharge nozzle discharges a photoresist onto a wafer. The metering pump supplies the photoresist of a fixed quantity into the discharge nozzle. The trap tank temporarily stores the photoresist to be supplied from the metering pump to the discharge nozzle. The bottle contains the photoresist stored in the trap tank. The bubble discernment member determines whether bubbles exist in the standby photoresist to be supplied from the pump to the discharge nozzle. The first drain line connects the pump to a waste liquid tank to drain the standby photoresist from the pump to the waste liquid tank when the bubble discernment member checks the bubbles.

### CROSS-REFERENCE TO RELATED APPLICATIONS

This U.S. non-provisional patent application claims priority under 35 U.S.C. § 119 of Korean Patent Application No. 10-2008-0089155, filed on Sep. 10, 2008, the entire contents of which are hereby incorporated by reference.

### BACKGROUND OF THE INVENTION

The present invention disclosed herein relates to an apparatus used for manufacturing a semiconductor device, and more particularly, to a photoresist supply apparatus used in a photolithography process for manufacturing a semiconductor device and a photoresist supply method.

A semiconductor device is manufactured by performing a large number of processes ranging from a wafer manufacturing process to a semiconductor assembling process. That is, the processes for manufacturing the semiconductor device include a thin film formation process for forming a thin film on a wafer, an ion implantation process for implanting impurities ions into the wafer, and a photolithography process for patterning the thin film formed on the wafer. A photoresist is used to form patterns in the photolithography process.

The photoresist is coated on the wafer with a thin thickness, and then, the photoresist is etched to form photoresist patterns through an exposure process. The photoresist is coated by directly and pressingly inserting an inert gas into a resist bottle. The method of directly and pressingly inserting the inert gas is affected by discharge reproducibility due to performance, a bubble, and a pipe size. Specifically, in the method of directly and pressingly inserting the inert gas, a discharge pressure is affected according to a capacity change of an inside of the resist bottle, thereby changing a discharge flow rate and suck back reproducibility.

Thus, there is a limitation that the photoresist is not discharged in a fixed quantity, and the photoresist to be coated on the wafer is not coated in a uniform thickness, so that a yield of the wafer is reduced. Also, in case where a discharge error of the photoresist occurs, it is difficult to quickly detect process failure because equipment for detecting the process failure does not exist.

### SUMMARY OF THE INVENTION

The present invention provides a photoresist supply apparatus capable of supplying a photoresist in a fixed quantity and a photoresist supply method.

The present invention also provides a photoresist supply apparatus capable of previously detecting whether a photoresist is discharged in a fixed quantity and a bubble exists and a photoresist supply method.

Embodiments of the present invention provide photoresist supply apparatuses including: a bottle containing a photoresist; a trap tank receiving the photoresist from the bottle to store the received photoresist; and a pump receiving the photoresist from the trap tank to supply the photoresist of a fixed quantity into a discharge nozzle for discharging the photoresist onto a wafer.

In some embodiments, photoresist supply apparatuses may further include: a pressure sensor detecting an internal pressure of the pump; and a controller comparing a measurement pressure value measured by the pressure sensor of the pump with a reference pressure value to determine whether bubbles exist in the photoresist to be supplied through the pump.

In other embodiments, photoresist supply apparatuses may further include a supply line and a first drain line connected to an outlet port of the pump.

In still other embodiments, photoresist supply apparatuses may further include: a filter disposed in a supply line connecting the pump to the discharge nozzle, the filter filtering foreign substances and bubbles contained in the photoresist; and a second drain line draining the photoresist containing the foreign substances and the bubbles filtered by the filter.

In other embodiments of the present invention, photoresist supply apparatuses include: a discharge nozzle discharging a photoresist onto a wafer; a pump supplying the photoresist of a fixed quantity into the discharge nozzle; a trap tank temporarily storing the photoresist to be supplied from the pump to the discharge nozzle; a bottle containing the photoresist stored in the trap tank; a bubble discernment member determining whether bubbles exist in the standby photoresist to be supplied from the pump to the discharge nozzle; and a first drain line connecting the pump to a waste liquid tank to drain the standby photoresist from the pump to the waste liquid tank when the bubble discernment member checks the bubbles.

In some embodiments, bubble discernment member may include: a pressure sensor detecting an internal pressure of the pump; and a controller comparing a measurement pressure value measured by the pressure sensor of the pump with a reference pressure value to check whether bubbles exist in the photoresist to be supplied through the pump, thereby opening and closing the first drain line.

In other embodiments, the bottle and the trap tank may be connected to an inert gas supply line to fill the bottle and the trap tank with an inert gas by an amount of the inert gas discharged through the discharge nozzle.

In still other embodiments of the present invention, photoresist supply methods include: temporarily storing a photoresist contained in a bottle in a trap tank; and performing a suction operation of a pump to fill a pump chamber of the pump with the photoresist stored in the trap tank, and performing a drain operation to supply the photoresist filled in the pump chamber into a discharge nozzle, wherein the performing of the suction and drain operations comprises comparing a measurement pressure value measuring an internal pressure of the pump with a reference pressure value before the photoresist filled in the pump chamber of the pump is supplied into the discharge nozzle to detect whether bubbles exist in the photoresist filled in the pump chamber of the pump.

In some embodiments, in the performing of the suction and drain operations, when the bubbles exist in the photoresist filled in the pump chamber of the pump, the photoresist filled in the pump chamber may be drained through a drain line due to the drain operation of the pump.

In other embodiments, the trap tank may be filled with an inert gas by an amount of the inert gas used in the performing of the suction and drain operations.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a schematic view of a photoresist supply apparatus according to an embodiment of the present invention;

FIGS. 2 and 3 are respective views illustrating a suction operation and a drain operation of a pump adapted to the embodiment; and

FIG. 4 is a flowchart illustrating a process of supplying a photoresist.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

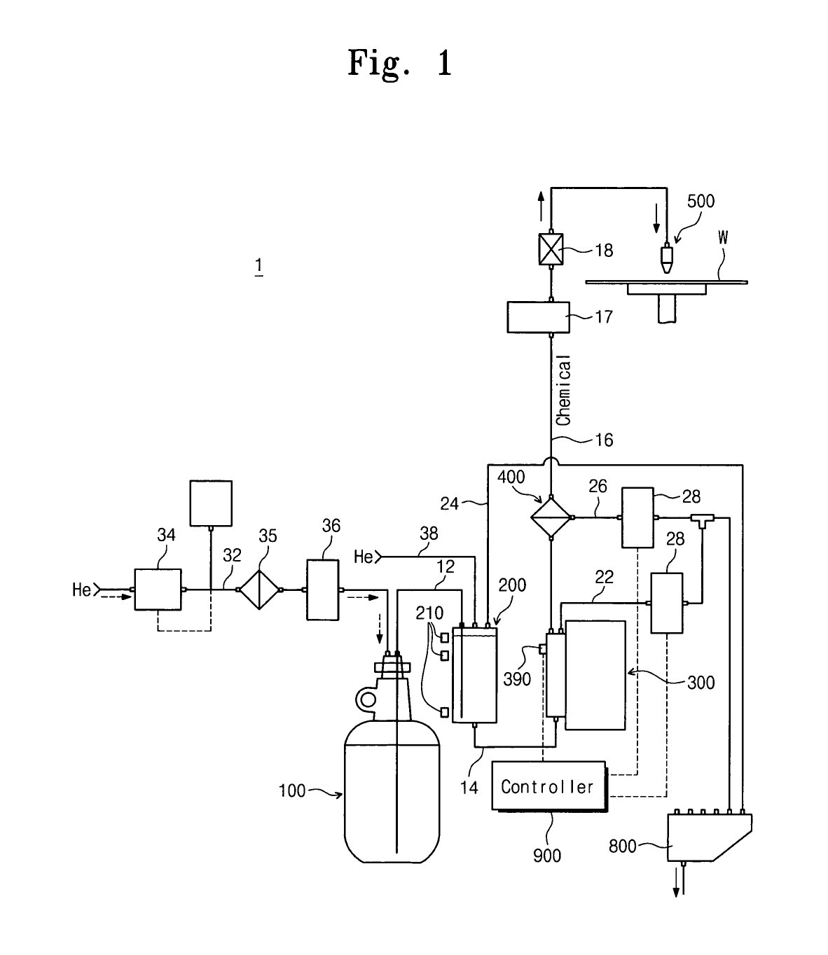

FIG. 1 is a schematic view of a photoresist supply apparatus according to an embodiment of the present invention.

Referring to FIG. 1, a photoresist supply apparatus 1 includes a bottle 100, a trap tank 200, a pump 300, a filter 400, and a discharge nozzle 500.

The bottle 100 is filled with a photoresist and connected to a first inert gas supply line 32 and a first supply line 12. An inert gas (e.g., a helium gas or a nitrogen gas) is supplied through a regulator 34 into the bottle 100 to maintain an inert gas atmosphere inside the bottle 100 sealed through the first inert gas supply line 32. The photoresist within the bottle 100 is moved into the trap tank 200 through the first supply line 12 due to a relative pressure therebetween. The regulator 34, a gas filter 35, and an air-operated valve 36 is installed at the first inert gas supply line 32 in order of precedence. The air-operated valve 36 is closed only when the bottle 100 is replaced.

The trap tank is supplied with the photoresist supplied through the first supply line 12 and stores the supplied photoresist. Level sensors 210 are installed a side of the trap tank 200 to detect a quantity level of the photoresist stored in the trap tank 200. The trap tank 200 is continuously supplied with the photoresist until the quantity level detected by the level sensors 210 same an appropriate quantity level. A second drain line 24 is connected to an upper end of the trap tank 200. The second drain line 24 removes bubbles accumulated in an upper portion of the trap tank 200 or passively drain according to variation of photoresist properties. The bubbles drained through the second drain line 24 and the property-varied photoresist are stored in a waste liquid tank 800. A second supply line 14 is connected to a bottom surface of the trap tank 200. The second supply line 14 is connected to an inlet port 302 of the pump 300.

The pump 300 supplies the photoresist stored in the trap tank 200 due to a flow pressure generated by suction and drain operations into the discharge nozzle 500 in a fixed quantity. The pump 300 suctions the photoresist in an amount required for performing a coating process on one wafer once from the trap tank 200 to a pump chamber 310, and then drains the photoresist with a uniform pressure and flow rate through the discharge nozzle 500 during a coating process. A bellows type tube-phragm pump is applied in this embodiment.

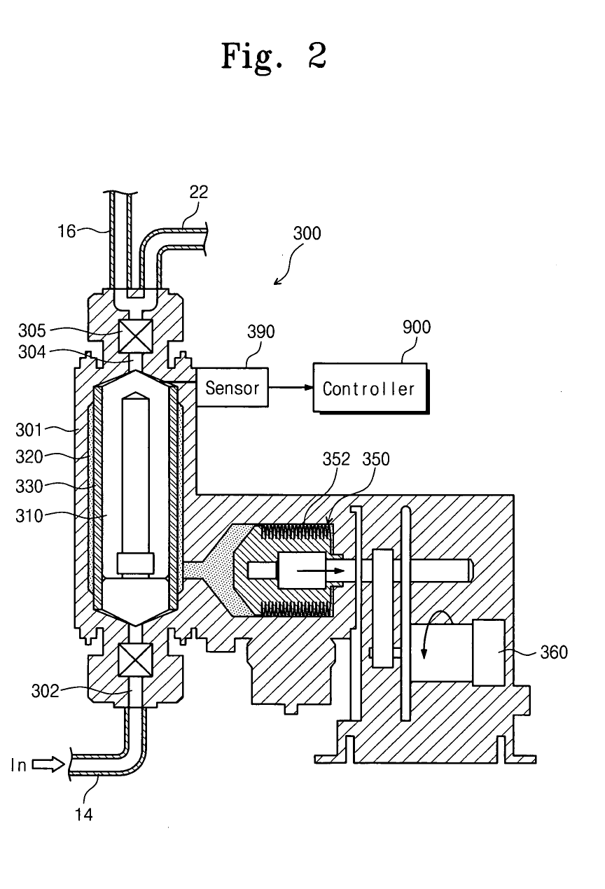

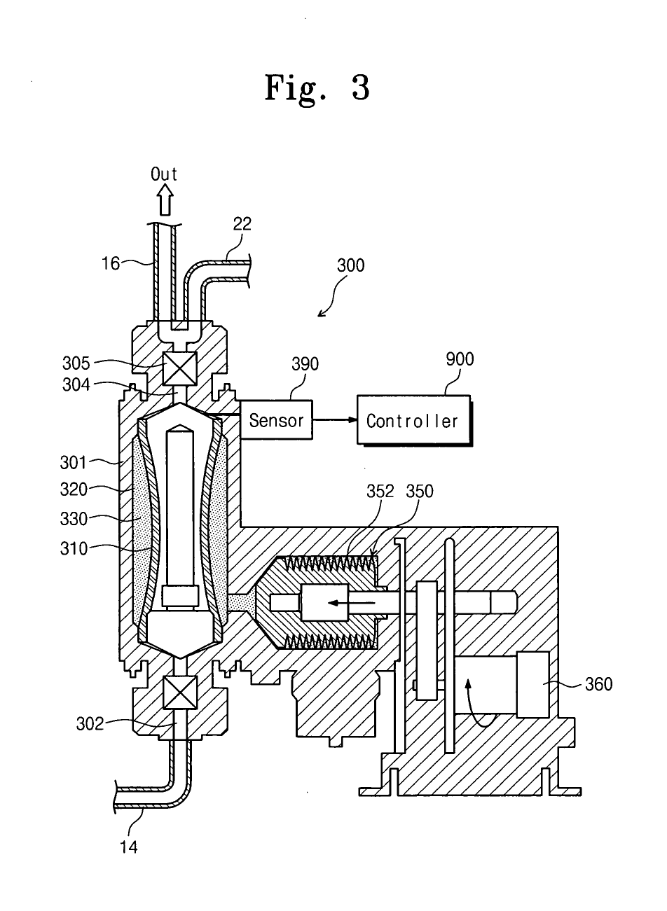

FIGS. 2 and 3 are respective views illustrating a suction operation and a discharge operation of a pump adapted to the embodiment.

Referring to FIGS. 1 and 2, the pump 300 includes a housing 301 with a variable capacity tube-phragm (an elastic septum) 330 separating a driving chamber 320 from the pump chamber 310 communicating with the inlet port 302 and an outlet port 304. A working fluid that is an incompressible medium is a medium for transmitting a driving force generated by stretch of a bellows portion 350 to the tube-phragm 330. A bellows 352 of the bellows portion 350 is driven by a stepping motor 360 and controlled according to conditions such as a stretching operation timing or a stretching speed, suction and discharge timings of the photoresist, and a discharge pressure under the control of a controller 900. Backflow preventing valves 305 are disposed in the inlet port 302 and the outlet port 304 of the pump 300, respectively. The outlet port 304 is connected to a third supply line 16 connected to the discharge nozzle 500 and a first drain line 22 connected to the waste liquid tank 800. A suck back valve 17, a cut-off valve 18, and the filter 400 are disposed in the third supply line 16. A third drain line 26 is connected to the filter 400 to remove bubbles accumulated in an upper portion of the filter 400. Air-operated valves 28 are disposed in the second drain line 24 and the third drain line 26, respectively.

FIG. 2 is a view illustrating a suction operation of the motor. Referring to FIG. 2, when the bellows 360 retreats in a rear direction by the stepping motor 360, the working fluid moves from the driving chamber 320 to the bellows portion 350 to reduce a pressure within the driving chamber 320. When the tube-phragm 330 is contracted due to the pressure drop of the driving chamber 320, a predetermined amount (amount required for performing the coating process once) of the photoresist is suctioned from the trap tank 200 to the pump chamber 310.

FIG. 3 is a view illustrating a drain operation of the motor. Referring to FIGS. 1 and 3, when the bellows 360 proceeds in a front direction by the stepping motor 360, the working fluid moves from the bellows portion 350 to driving chamber 320 to raise a pressure within the driving chamber 320. As a result, the tube-phragm 330 is expanded due to the pressure raise of the driving chamber 320 to discharge the photoresist filled in the pump chamber 310 to the discharge nozzle 500 through the third supply line 16.

A pressure sensor 390 is disposed in the pump 300 to detect a photoresist pressure within the pump chamber 310. A measurement pressure value measured by the pressure sensor 390 is provided to the controller 900. The controller 900 compares the measurement pressure value with a previously set pressure value (a reference pressure value). A measurement pressure value in case where the bubbles exist in the photoresist filled in the pump chamber 310 is different from a measurement pressure value in case where the bubbles do not exist in the photoresist. Therefore, it can detect whether the bubbles are contained in the photoresist, before the photoresist is supplied to the discharge nozzle 500. In the current exemplary embodiment, the pressure sensor 390 and the controller 900 serve as a bubble discernment member that determines whether the bubbles are contained in the photoresist filled in the pump chamber 3110 for supplying the photoresist from the pump 300 to the discharge nozzle 500.

When the bubbles are detected in the photoresist filled in the pump chamber 310 of the pump 300, the pump 300 operates to drain the photoresist filled in the pump chamber 310 to the waste liquid tank 800 through the first drain line 22.

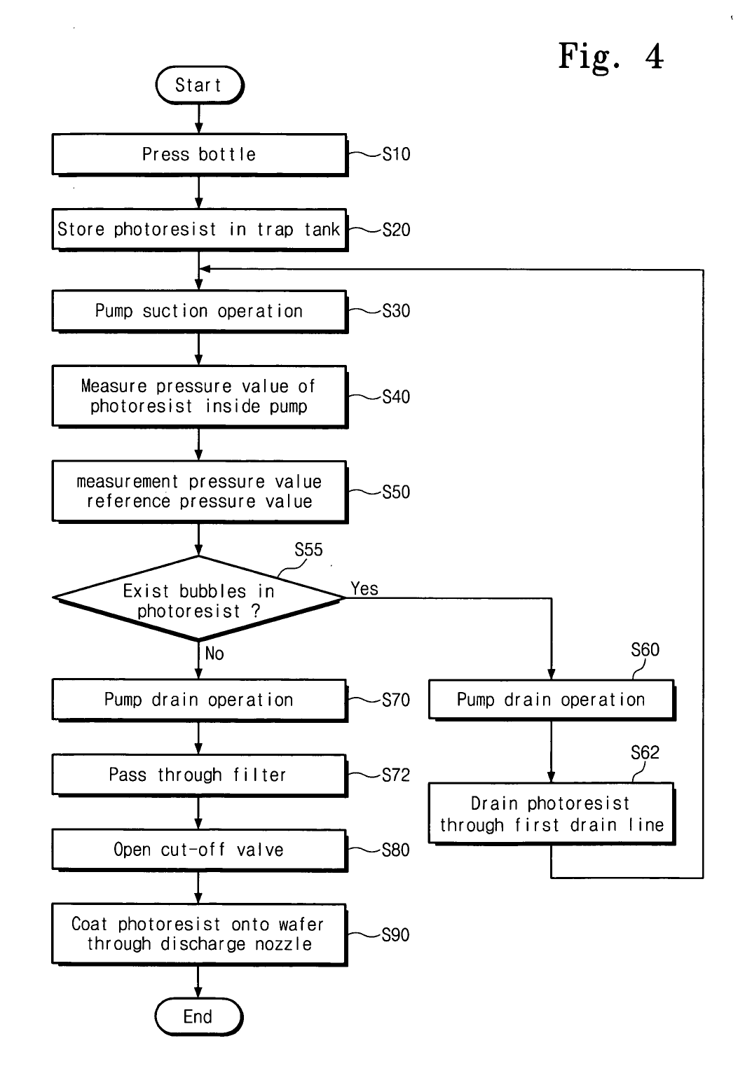

FIG. 4 is a flowchart illustrating a process of supplying a photoresist.

Referring to FIGS. 1 to 4, in operations S10 and S20, a photoresist contained in a bottle 100 is discharged from the bottle 100 due to a press of an inert gas being supplied into the bottle 100, and the discharged photoresist from the bottle 100 is temporarily stored in a trap tank 200.

In operation S30, the photoresist stored in the trap tank 200 moves into a pump chamber 310 of a pump 300 due to a suction operation of the pump 310. In operation S40, a pressure sensor 390 measures a pressure value (discharge pressure) of the photoresist filled in the pump chamber 310. The pressure value measured by the pressure sensor 390 is provided to a controller 900. In operation S50, the controller 900 compares the measured pressure value with a reference pressure value. In operation S55, the controller 900 checks whether a difference value between the measured pressure value and the reference pressure value is in a predetermined difference value range so as to detect whether the bubbles exist in the photoresist filled in the pump chamber 310 of pump 300 and whether the photoresist is discharged in a fixed quantity. In the current exemplary embodiment, the predetermined difference value range includes values corresponding to an acceptable range of bubbles contained in the photoresist. When the difference value is in excess of the predetermined difference value, the controller 900 determines that the bubbles exist in the photoresist. In this case, it is impossible to discharge the photoresist in the fixed quantity. Thus, the pump 300 operates to drain the photoresist filled in the pump chamber 310 through a first drain line 22 in operation S60. Thereafter, the pump 300 operates again to fill the pump chamber 310 with a photoresist.

On the other hand, when the difference value between the measured pressure value and the reference pressure value is less than the predetermined value, the pump 300 performs a drain operation in operation S70 to drain the photoresist into a third supply line 16. The drained photoresist passes through a filter 400 in operation S72, and then a cut-off valve 18 is opened in operation S80 to coat the photoresist onto a wafer through a discharge nozzle in operation S90.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A photoresist supply apparatus, comprising:
a bottle containing a photoresist;
a trap tank receiving the photoresist from the bottle to store the received photoresist; and
a pump receiving the photoresist from the trap tank to supply the photoresist of a fixed quantity into a discharge nozzle for discharging the photoresist onto a wafer.

2. The photoresist supply apparatus of claim 1, further comprising:
a pressure sensor detecting an internal pressure of the pump; and
a controller comparing a measurement pressure value measured by the pressure sensor of the pump with a reference pressure value to determine whether bubbles exist in the photoresist to be supplied through the pump.

3. The photoresist supply apparatus of claim 1, further comprising a supply line and a first drain line connected to an outlet port of the pump.

4. The photoresist supply apparatus of claim 1, further comprising:
a filter disposed in a supply line connecting the pump to the discharge nozzle, the filter filtering foreign substances and bubbles contained in the photoresist; and
a second drain line draining the photoresist containing the foreign substances and the bubbles filtered by the filter.

5. A photoresist supply apparatus, comprising:
a discharge nozzle discharging a photoresist onto a wafer;
a pump supplying the photoresist of a fixed quantity into the discharge nozzle;
a trap tank temporarily storing the photoresist to be supplied from the pump to the discharge nozzle;
a bottle containing the photoresist stored in the trap tank;
a bubble discernment member determining whether bubbles exist in the standby photoresist to be supplied from the pump to the discharge nozzle; and
a first drain line connecting the pump to a waste liquid tank to drain the standby photoresist from the pump to the waste liquid tank when the bubble discernment member checks the bubbles.

6. The photoresist supply apparatus of claim 5, wherein bubble discernment member comprises:
a pressure sensor detecting an internal pressure of the pump; and
a controller comparing a measurement pressure value measured by the pressure sensor of the pump with a reference pressure value to check whether bubbles exist in the photoresist to be supplied through the pump, thereby opening and closing the first drain line.

7. The photoresist supply apparatus of claim 5, wherein the bottle and the trap tank are connected to an inert gas supply line to fill the bottle and the trap tank with an inert gas by an amount of the inert gas discharged through the discharge nozzle.

8. A photoresist supply method, comprising:
temporarily storing a photoresist contained in a bottle in a trap tank; and
performing a suction operation of a pump to fill a pump chamber of the pump with the photoresist stored in the trap tank, and performing a drain operation to supply the photoresist filled in the pump chamber into a discharge nozzle,
wherein the performing of the suction and drain operations comprises comparing a measurement pressure value measuring an internal pressure of the pump with a reference pressure value before the photoresist filled in the pump chamber of the pump is supplied into the discharge nozzle to detect whether bubbles exist in the photoresist filled in the pump chamber of the pump.

9. The method of claim 8, wherein, in the performing of the suction and drain operations, when the bubbles exist in the photoresist filled in the pump chamber of the pump, the photoresist filled in the pump chamber is drained through a drain line due to the drain operation of the pump.

10. The method of claim 8, wherein the trap tank is filled with an inert gas by an amount of the inert gas used in the performing of the suction and drain operations.
